(19) United States
(12) Patent Application Publication
(10) Pub. No.: US 2004/0051173 A1
(43) Pub. Date: Mar. 18, 2004

(54) High frequency interconnect system using micromachined plugs and sockets

(76) Inventors: Philip Joseph Koh, Centreville, VA (US); Steven Michael Marazita, Charlottesville, VA (US); David Thompson Nemeth, Washington, DC (US)

Correspondence Address: SUGHRUE MION, PLLC, 2100 PENNSYLVANIA AVENUE, N.W., SUITE 800, WASHINGTON, DC, 20037, US

(21) Appl. No.: 10/433,901

(22) PCT Filed: Dec. 10, 2001
(86) PCT No.: PCT/US01/47206

(51) Int. Cl. H01L 23/34

(52) U.S. Cl. 257/728

(57) ABSTRACT

A high frequency interconnect packaging and assembly system (FIG. 25).

### RELATED APPLICATION

The present Application claims priority from the co-pending U.S. Provisional Patent Application Serial No. 60/254,243 filed Dec. 8, 2000, the disclosure of which is incorporated herein by reference.

### BACKGROUND OF THE INVENTION

The present invention relates to micromachined packaging and assembly systems useful, for example, for high frequency circuits.

The integration of Monolithic Microwave Integrated Circuits (MMIC's) into high frequency communication systems and devices has increased the need for low cost packaging and interconnecting systems that can be mass produced.

Silicon micromachining has been used, for example, to fabricate accurate three dimensional geometries. Microwave systems require the integration of electronic devices with precise three dimensional structures whose dimensions will have a strong effect on the electrical performance of the system. In the millimeter wave region in particular, traditional electronic packaging and assembly techniques yield poor performance and repeatability.

An example of the use of micromachining in the field of MMIC's is found in U.S. application Ser. No. 09/752,725, for “A High Frequency, Low Cost Package For Semiconductor Devices,” the disclosure of which is herein incorporated by reference.

By using micromachined plugs and sockets, very accurate geometries can be achieved, allowing a well controlled and repeatable connection. This well controlled geometry is crucial when the signals are in the millimeter wave range. In making micromachined plugs and sockets, sloped sidewalls are generally desirable. These sloped sidewalls should have substantially the same angle, thereby giving a near-perfect fit.

In order for a plug to slide into a socket, it is helpful if the plug is narrower at the end and wider at the base. This allows room when first inserting the plug, which can then squeeze in and fit snugly when fully inserted. This requires an angled wall somewhere along the length of the plug. However, angled walls tend to etch back a considerable distance during the deep silicon etch, thus requiring a longer plug which consumes greater wafer real estate and negatively impacts the device yield per wafer.

A common micromachining technique for constructing silicon shapes or devices, e.g. angled or sloped walls, is to mask the silicon with some patterned thin film and etch it in an anisotropic etchant, such as Tetra Methyl Ammonium Hydroxide (hereinafter TMAH). Patterned mask layers might include thermal oxide, deposited oxide, deposited nitride, deposited metal, etc. The thin film can be patterned using standard photolithography and etching techniques.

Although silicon is the most often used single crystal material which is used for micromaching, other forms of silicon and other materials are also possible to use. Some of these may have similar etching properties in anisoptropic etchants as silicon, and the discussion here of etching silicon would also apply to those materials.

The final shape of the silicon is determined by the mask pattern, the etch time, and the crystal orientation of the silicon. Most anisotropic etches of silicon behave in similar ways and give similar geometries. Further examples of crystalline etchants are potassium hydroxide (KOH) and ethyl-diamine pyrokotechol (EDA-P).

One of the problems when designing masks for etching silicon structures is that these etches undercut corners. Mask compensation techniques can be used so that the final structure has the intended corner.

For <100> wafers, one difficulty with this is that the corner undercut rate is several times faster than the rate at which the wafer etches down. A 15 mil thick wafer might experience 100 mils of corner undercut before it is etched through. Specifically, during Si etching, the exposed interior angles, which are square in the mask, are instead etched to a faceted, somewhat rounded profile due to the crystal structure. A large square or circle superimposed on an exterior 90 degree angle is typically used to protect that square corner. Because of this, corner protectors in the past have tended to be large. Etch timing is then used to get the corner exactly square at the end of the Si etch.

For example, FIG. 1 shows a well-known corner protector design for a <100> wafer 1. The black area 2, 2′ is the area of the silicon wafer 1 that is protected by the masking layer. The white area 4 is the area of the silicon wafer 1 that is not protected by the masking layer and is intended to be exposed to the anisotropic etchant. The series of images in FIGS. 1a, 1b, 1c, and 1d illustrate, roughly, how the silicon 2, 2′ evolves over time, as the etch progresses. The silicon area 2′ is known as the corner protector. As shown in FIGS. 1b, 1c, and 1d, although protected by the original masking layer, the silicon area 2′, or corner protector, is nevertheless attacked by the anisotropic etchant. The etching undercuts the protective masking layer causing the silicon area 2′ to etch away completely. After the etching is complete, the silicon area 2, which is the intended shape, is all that remains of the silicon area 2, 2′. The problem with this design, however, is that corner protector designs of this type tend to be large.

FIG. 2 shows another type of well known corner protector design using a stub 3 in lieu of a larger two-dimensional shape of FIG. 1. The silicon area 4 is unprotected by the masking layer, while the silicon area 2, 3 is protected by the masking layer. The etch progress of the silicon area 2, 3 is shown by the series of images in FIGS. 2a, 2b, and 2c. The stub 3 is etched from underneath the masking layer during the etching process. When the etching process is complete, the stub 3 will have been etched away and the silicon area 2 will remain.

This stub-type corner protector 3 will fit in some geometries that the larger two-dimensional shaped corner protector, shown in FIG. 1, will not fit. However, in the stub-type corner protector, the stub 3 must still be several times longer than the thickness of the wafer. Because of this length requirement, the stub-type corner protector does not easily fit in a tight space, and, therefore, may necessitate putting fewer devices on a wafer. Accordingly, fewer devices per wafer correlates to a greater number of wafers required, and thus, higher manufacturing costs.

Another problem when designing masks for etching silicon structures by the use of anisotropic etchants is that, during etching, the silicon area underneath an angled wall in the masking layer, which is intended to be protected, will nevertheless be attacked by the etchant, causing the silicon area under the angled wall to propagate backwards at some well defined speed. This propagation, like the corner etchback, happens at several times the speed at which the etching process etches through the wafer 1. The design should include an adequate additional silicon area above the tapered or angled feature to be etched away during the etching process, so that, when the etch is complete, the resulting tapered silicon feature is at the proper location. Again, mask compensation techniques can be used so that, upon completion of the etching, the final structure has the intended angled wall.

A common way to include an angled wall is shown in FIGS. 3a and 3b. To compensate for the undercutting of the silicon under the angled wall feature of the masking layer, an additional area of silicon 2′ is protected by the masking layer so that as the etching process is performed, the silicon 2′ under the angled wall mask will be etched away. After the etching process is complete, the silicon 2 under the desired angle wall will remain. However, the additional amount of silicon area 2′ required in this design occupies more of the wafer 1 area than is desirable.

Another problem with known millimeter wave packaging and assembly systems is that in the interlock system, a problem could arise if the plug and socket have some small amount of looseness based on the tolerances on lithography, wafer thickness, flatness, etc., that would permit the surfaces to lose contact with each other. It is therefore necessary to ensure that the contacts on the plug and receptacle of the millimeter wave package interlock system come into intimate contact with each other, despite these variations in tolerances. In order to solve this problem, some degree of compliance or “springiness” is needed in the contact area.

A known method of providing compliance in an interlock millimeter wave system is the use of a long silicon cantilever used to press the surfaces together. However, when using a silicon cantilever to provide compliance, the physical characteristics of silicon limit the ability to reduce the cantilever size, thereby limiting the ability to limit the package size. Package size is inversely proportional to die yield per wafer, as well as circuit packing density. Therefore, by providing a different and improved compliant mechanism to mate the surfaces together, the long silicon cantilever can be eliminated and the package size can be greatly reduced.

Yet another problem with known millimeter wave packaging and assembly systems is in the surface mounting of packages using solder. It is known to surface mount packages with solder to provide a path for the RF signal down to a circuit board. In addition, it is known to surface mount packages with solder to mechanically bond the packages together. However, FIGS. 4a-4c depict one of the problems with surface mounting packages with solder. Part (a) shows a solder bump 70 on a surface 72. Surface 71 will be attached to surface 72. Even if the amount of solder 70 is very well controlled (which is not difficult to achieve through a variety of methods, including electroplating), the final height and width of the solder 70′ depends on the final separation of the two surfaces 71, 72. This distance is not well controlled, and depends on the force applied to the two surfaces 71, 72, particles on the surfaces 71, 72, and other difficult to control factors. This variation presents two problems as it relates to making millimeter wave interconnects. The first problem is that, as the surfaces 71 and 72 are pressed together and the solder is heated, the solder spreads laterally. If the solder spreads far enough, the solder may come into contact with other adjacent solder bumps or contact lines, thereby causing a short between the adjacent solder bumps or between the solder bump and an adjacent conductor line. The second problem is that variations in height and width of the solder 70′, after the solder has spread laterally, causes capacitance and coupling variations in the interconnect structure, which causes unpredictable performance and can seriously degrade the RF signal path from the package to circuit board.

Yet another problem with fabricating micromachined packages relates to wafer bonding. One bonding technique is to apply an intermediate layer, such as solder, over selected portions of one or both of the wafers to be bonded. The wafers are then aligned and pressed together with some force. While the force is maintained, the wafers are heated up, and the intermediate layer melts and flows. The wafers are cooled, the intermediate layer solidifies, and the wafers are bonded in selected areas. By using a conductive intermediate layer, such as solder, electrical contact can be made between the metal on the top and the bottom of the wafers. However, when forming a plug and socket system, the mechanical strength of the bond is also important. Because of this, the intermediate layer may be deposited over a relatively large area. When the wafers are brought together and heated, the pressure can force the liquid intermediate layer to flow outside the area where it was deposited, causing short circuits, bumps along the edges of the package, and other problems. Because the intermediate layer may be deposited over a large area, there is a larger amount of material from the intermediate layer that may flow laterally.

Yet another problem with micromachined packaging and assembly is that known transitions from the micromachined package to a conventional connector cannot be assembled using automated assembly equipment, rather, manual connections must be made. For example, there are several problems with current high frequency circuit board to connector transitions. Connections based around dielectric supported center pin terminals (such as straight terminal panel mount) do not withstand hermeticity requirements of many electronic systems. Also, connector gender cannot be exchanged without opening the internal housing and de-soldering the center pin contact. This is too disruptive, especially with systems already installed in the field.

The known solution to these problems is field replaceable connector technology which uses a soldered in glass bead with pin through its center to provide a wideband 50 ohm transition through a housing wall while maintaining a hermetic seal to the outside world. An example of a glass bad to microstrip transition is shown in FIG. 5 and is produced by Anritsu Company (K Connector Microstrip to K Female Flange Mount Connector, Part Number K103F). The bead 110 interfaces with a connector on the outside that can be swapped easily for male or female without intruding into the package. On the inside of the package, the center pin 112 sticks past the glass bead 110 into an air dielectric area 114 which forms a coaxial connection with a circular hole 116 cut in the metal housing wall 118. The pin 112 protrudes into the housing 118 where it interfaces with a circuit board 120 by soldering the center pin 112 to a microstrip line 122 running on a dielectric circuit. The solder is shown at points 124 and 126.

The problems and limitations of the glass bead to microstrip transition are numerous. The distance that the pin protrudes before it makes good electrical connection to the microstrip circuit board is critical and must be minimized at higher frequencies to eliminate inductive transmission line effects from degrading transition performance. This makes it nearly impossible to use automated assembly equipment for this transition because the short pin extension places it next to a high aspect ratio housing or package wall that the automated machine cannot reach down into and access to apply epoxy or solder the pin to a circuit. Additionally, manual wire and ribbon bond connections cannot reach deep into packages at the wall edges. This limits design flexibility and can compromise RF performance. This assembly, therefore, is typically performed manually and therefore is not compatible with high volume manufacturing. Additionally, the circuit board placement into the housing cannot be automated if the glass bead pin is installed first because the circuit board must be slipped underneath the protruding pin from the side, a difficult operation for a machine to accomplish. Forcing the manufacturer to install the glass bead pin after circuit board mounting severely limits process design flexibility and puts strict requirements on temperature cycling, solder types available for use, and restricts populating the circuit board with bare die until the glass bead is installed. Bare die are still in frequent use in the millimeter wave frequency range as well as in optoelectronic applications.

Extending the pin further out into the housing to pull it away from housing wall does not improve the problem. Pulling the circuit away from the housing wall increases the phase length of the high impedance pin transmission line (since it does not have a ground shield around it after exiting the housing wall) and therefore degrades performance rapidly. Any overlap with the microstrip line must be electrically connected to avoid a tuning stub effect. Even if the pin is pulled out farther into the housing, at high frequency, the end of the pin cannot be wirebonded to the circuit board if the circuit board hovers below the pin without being electrically connected along its entire length.

Additionally, the necessity of using epoxy or soldering from pin to circuit creates a coefficient of thermal matching problem from circuit to pin. All connections are rigid and unforgiving, and therefore careful mechanical design must be considered as the housing or package is ramped over standard operating temperature ranges.

Lastly, the traditional glass bead pin transition mates naturally to a microstrip circuit board, but is not compatible with other circuit board transmission line topologies such as co-planar waveguide. This makes it difficult to get a constant impedance wideband transition over several frequency octaves since microstrip is a dispersive transmission line medium. Co-planar waveguides can be non-dispersive over many octaves of bandwidth. Co-planar waveguide is a co-planar transmission technology in which the ground planes are on the same plane as the center conductor on the circuit board. The ground plane in the glass bead to microstrip transition is at the bottom of the circuit board. Using via holes to abruptly transition from CPW to the glass bead pin is very challenging to get a broadband response due to the sudden disruption of current flow along the circuit board's top surface ground planes down to the housing floor. The designer is forced to convert to microstrip on the circuit board before the pin transition which takes up significantly more die or circuit board real estate, increases circuit losses, and adds complexity to the component.

### SUMMARY OF THE INVENTION

It is therefore an object of this invention to provide an improved packaging and assembly for a millimeter wave system.

It is another object of this invention to provide a packaging and assembly system that minimizes the wafer area per device.

It is still another object of this invention to provide improved reliability for packaging and assembly of a millimeter wave system.

It is yet another object of this invention to provide reduced area micromachined apparatus for providing compliance or conductive compliance between the opposing members of a millimeter wave interconnect system.

It is yet another object of this invention to provide micromachined or integrally formed surface mounts.

It is a further object of this invention to provide an improved method of waferbonding with an intermediate bonding layer.

It is yet another object of this invention to provide a transition from a glass bead to an Open Coax Shelf (or CPW shelf) and from an Open Coax Shelf (or CPW shelf) to a CPW or microstrip circuit on a conventional circuit board or a micromachined socket and plug interconnect and packaging system. The glass bead then interfaces with a standard RF connector which connects the internally interconnected packages and devices with the outside world.

Further objects, features and advantages of the invention will become apparent from a consideration of the following description and the appended claims when taken in connection with the accompanying drawings.

### BRIEF DESCRIPTION OF THE DRAWINGS

The above aspects of the present invention will become more apparent by describing in detail embodiments thereof with reference to the attached drawings, in which:

FIGS. 1a, 1b, 1c, and 1d are plan views depicting the mask propagation of a prior art corner protector.

FIGS. 2a, 2b, 2c, and 2d are plan views depicting the mask propagation of a prior art stub corner protector.

FIGS. 3a and 3b are plan views depicting the mask propagation of a prior art angled wall propagation technique.

FIGS. 4a, 4b, and 4c are a cross sectional views of a prior art solder bonding process.

FIG. 5 is a cross-sectional view of a known glass bead transition to a conventional circuit board.

FIGS. 6a, 6b, 6c, 6d, 6e, and 6f are plan views depicting the mask propagation of a non-limiting embodiment of a reduced area corner protector according to the present invention.

FIGS. 7a, 7b, 7c, 7d, and 7e are plan views depicting the mask propagation of another non-limiting embodiment of a reduced area corner protector according to the present invention.

FIGS. 8a, 8b, 8c, 8d, and 8e are plan views depicting the mask propagation of another non-limiting embodiment of a reduced area corner protector according to the present invention.

FIGS. 9a and 9b are cross sectional views of a corner protector with the entire underside of the wafer patterned by a masking layer according to a non-limiting embodiment of the present invention.

FIGS. 10a and 10b are cross sectional views of a corner protector with only a portion of the underside of the wafer patterned by a masking layer, according to a non-limiting embodiment of the present invention.

FIGS. 11a, 11b, and 11c are plan views depicting the mask propagation of a non-limiting embodiment of a reduced area angled wall propagation reduction apparatus according to the present invention.

FIGS. 12a, 12b, and 12c are plan views and cross sectional views depicting an non-limiting embodiment of a compliant structure method and apparatus according to the present invention.

FIG. 13 is a cross-sectional view of a compliant structure mating with an opposing surface according to the present invention.

FIG. 14 is a cross-sectional view of a compliant structure mating with an opposing surface having a bump, according to the present invention.

FIGS. 15a, 15b, and 15c are plan views and cross sectional views of another non-limiting embodiment of a compliant structure method and apparatus according to the present invention.

FIGS. 16a, 16b, 16c, 16d, and 16e are plan views and cross sectional views of another non-limiting embodiment of a compliant structure apparatus and method, including a bump, according to the present invention.

FIGS. 17a and 17b are cross-sectional views of another non-limiting embodiment of a compliant structure apparatus and method, with an undercut silicon wafer, according to the present invention.

FIG. 18 is a cross-sectional view of another non-limiting embodiment of a compliant structure apparatus and method, with an undercut silicon wafer and a bump formed on the compliant structure, according to the present invention.

FIG. 19 is a plan view of another non-limiting embodiment of a compliant structure apparatus and method, with an undercut silicon wafer, according to the present invention.

FIG. 20 is a plan view of another non-limiting embodiment of a compliant structure apparatus and method, with an undercut silicon wafer, according to the present invention.

FIGS. 21a and 21b are cross sectional views of a solder bonding process, including standoffs or stilts, according to a non-limiting embodiment of the present invention.

FIGS. 22A and 22B are cross-sectional views of a nickel and solder striping pattern according to a non-limiting embodiment of the present invention.

FIG. 23 is a cross-sectional view of a nickel and solder striping pattern according to a non-limiting embodiment of the present invention.

FIG. 24 is an isometric view of a glass bead to CPW shelf transition according to a non-limiting embodiment of the present invention.

FIG. 25 is an isometric view of a glass bead to CPW shelf transition according to a non-limiting embodiment of the present invention.

FIG. 26 is a plan view of a glass bead to CPW shelf transition according to a non-limiting embodiment of the present invention.

FIG. 27 is a side view of a glass bead to CPW transition according to a non-limiting embodiment of the present invention.

FIG. 28 is a plan view of a non-limiting embodiment of a compliant structure array, according to the present invention.

FIG. 29 is a plan view of a non-limiting embodiment of a compliant structure array, according to the present invention.

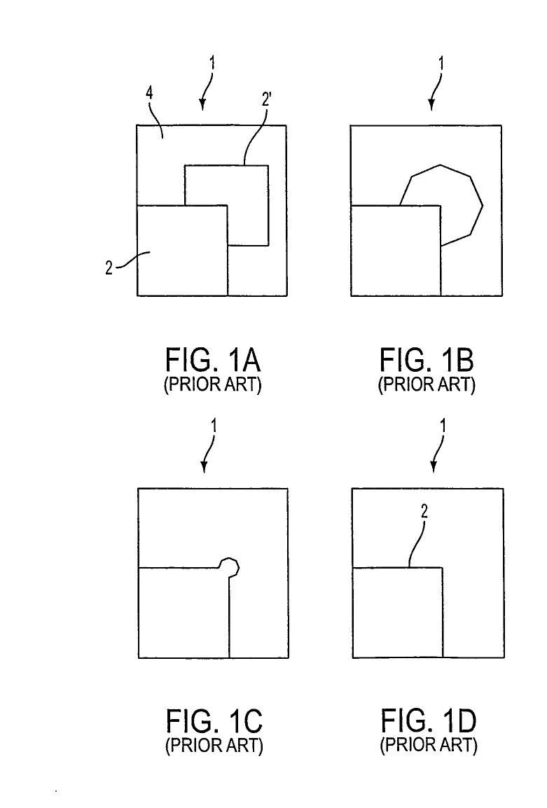

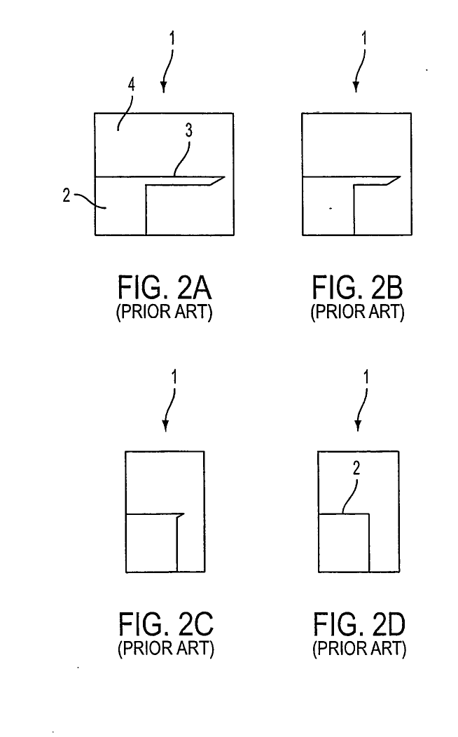

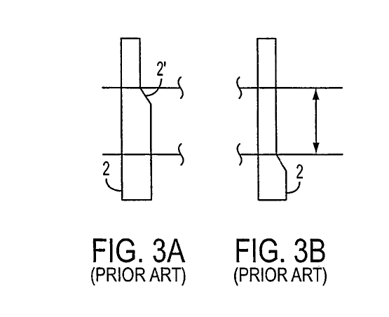

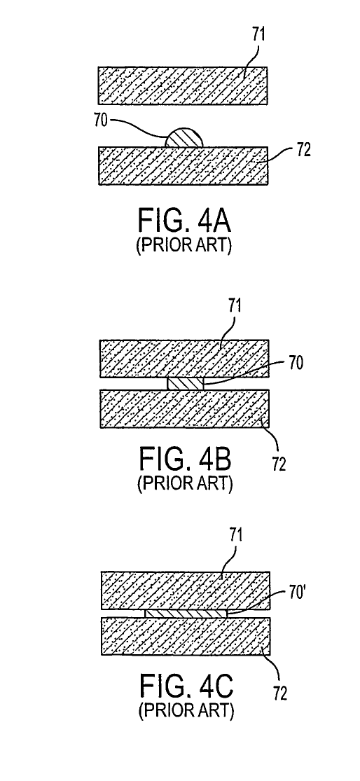

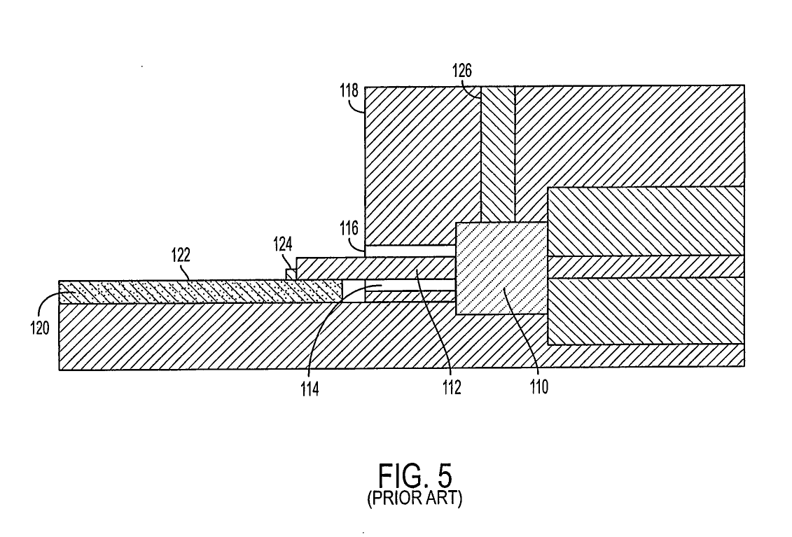

### DETAILED DESCRIPTION OF THE INVENTION

Hereinafter, embodiments of the present invention will be described in detail with reference to the attached drawings. The present invention is not restricted to the following embodiments, and many variations are possible within the spirit and scope of the present invention. The embodiments of the present invention are provided in order to more completely explain the present invention to one skilled in the art.

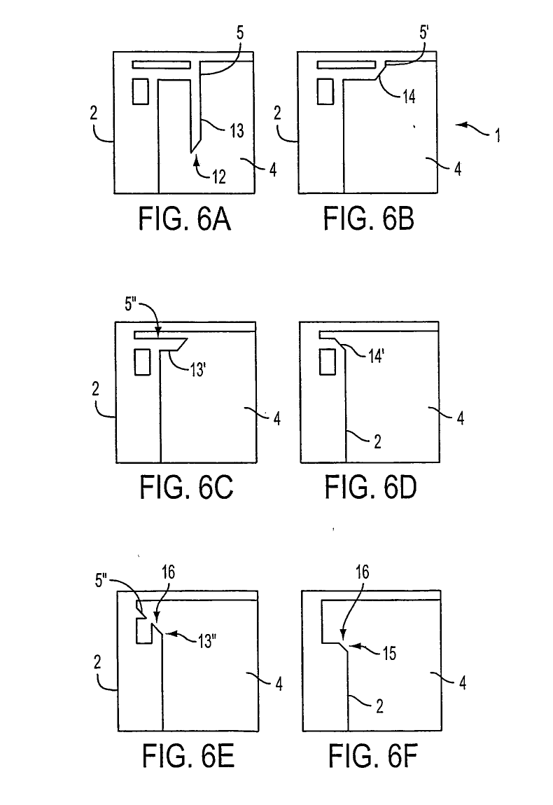

A non-limiting embodiment of a stub corner protector that solves the aforementioned problems, and others, is now described with reference to FIGS. 6a-6f. The black areas in FIG. 6a represent the silicon that is protected by a masking layer. The white areas represent the areas that are not protected by a masking layer and that will be exposed in the etching process. During the etching process, the silicon under the stub-type corner protector 13 is etched from underneath the masking layer, despite being covered by the masking layer. In this embodiment, a bend 14 can be made in the stub 13 so that the stub 13 can be folded, several times if necessary, to fit it in a smaller space on the wafer. The bend 14 should be positioned so that no corners in the silicon area 2, which is protected by a masking layer, are made except at the end of the stub 14. This is done by using “T” like structures to turn the corners, and connecting the extra pieces of the “T” 5, 5′ to the nearest wall. These little extra pieces 5, 5′ can be made short enough so that they are completely etched away during the etching process.

The stub 13 is folded around so that the length of the stub 13 runs down the length of the area to be etched away 4, reducing the space required on the wafer. The stub 13 can be folded more than once to fit into tight geometries. In the initial mask layout depicted in FIG. 6a, there is only a corner at the end 12 of the stub 13. Next, the stub 13 is etched back until the bend 14 is encountered, as depicted in FIG. 6b. The bend 14 is then etched into small stubs 13′ and 5′, depicted in FIGS. 6b and 6c, which are soon completely etched away. After stub 13′ is etched away, bend 14′ is encountered. The bend 14′ is then etched back into the remaining stubs 13″ and 5″, as shown in FIG. 6e, which continue to etch. The stubs 13″ and 5″ are then etched completely away, leaving the corner 15, as depicted in FIG. 6f.

The positions of the bends 14, 14′ must be put so that the small stubs 13′, 13″, and 5′, 5″ left over after the bends 14, 14′ are short enough to etch away entirely. Alternatively, the stubs 13, 13′ and 5′, 5″ can be located on surfaces that are not important to the device, so that if there are any portions of the stubs 13, 13′ and 5′, 5″ remaining after etching, the stubs 13, 13′ and 5′, 5″ will not affect the device.

In the embodiment described in FIGS. 6a-6f, the angle of the propagating etch front 16 results in a small piece being taken out of the corner 15. This etching of corner 15, if undesirable, can be minimized by making the stub 13″ narrower.

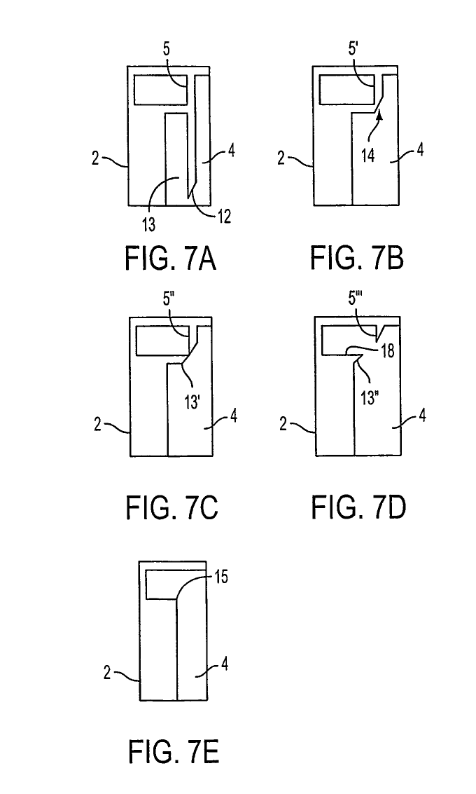

In addition, different geometries can be employed to reduce this etching effect on the corner 15. For example, FIGS. 7a-7e depict another embodiment of a stub-type corner protector 13 that, as it etches, changes the relative angle between the bend 14 and the final stub 13′, 13″ connecting the corner 15. The propagating etch front 18 is now in the opposite direction, which gives a better final corner 15.

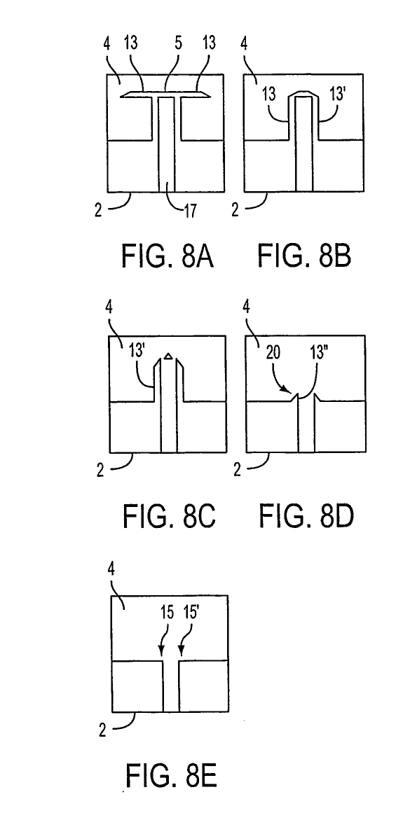

Yet another embodiment of the corner protectors is depicted in FIGS. 8a-8e. In this embodiment, the “T” shapes are joined together to achieve a fold 5, as depicted in FIG. 8a. This embodiment permits, for example, a socket to open up in the inside of a small cavity 17, where there wouldn't otherwise be room for corner protectors. FIGS. 8a-8e depict the propagation of the two folded silicon stubs 13 which are initially joined together. As depicted in FIG. 8e, the propagating etch front 20 of stub 13″, in this embodiment, is in an opposite direction as compared to the propagating etch front 16 in FIG. 6e. The angle of the propagation etch front 20 results in better final corners 15, 15′.

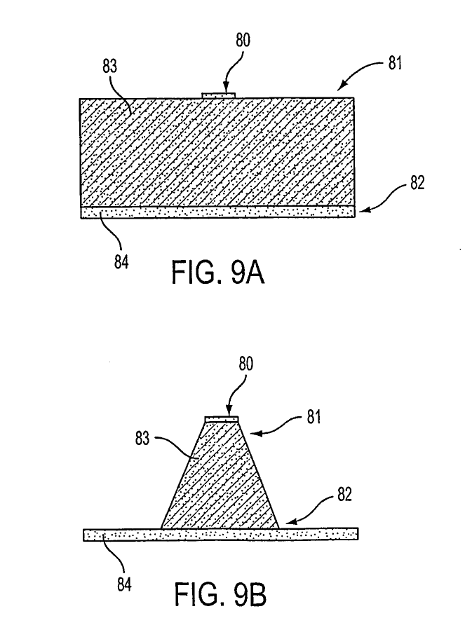

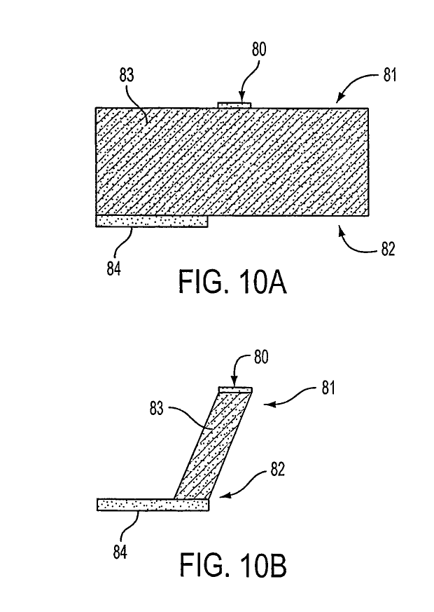

Another embodiment of the corner protector which results in a better final edge consists of the same stub structure, but with the wafer patterned and etched from both sides. FIGS. 9a and 9b depict cross sections of a stub resulting from a wafer 83 with masking layer 80 on one side 81 and masking layer 84 on the other side. In FIGS. 9a and 9b, the mask layer covers the entire underside of the wafer 83, resulting in a device having a wider bottom portion 82 and a thinner top portion 81. However, if a masking layer 80 is used on one side and a masking layer 85 is used on the underside of the wafer 83, as shown in FIGS. 10a and 10b, the final propagating stub will not be wider at the bottom 82 than the top 81, so less additional etching will be required to consume the bottom 82 of the stub after the top 81 is completely gone. This will result in a sharper corner, because the top 81 will not be over etched while the etching process continues to consume the bottom 82. Of course, this technique requires the alignment of the frontside 80 and backside 84 masking layer patterns. Only the last part of the stub structure needs to be treated in this way, as it is only the last bit of etching which needs to finish evenly.

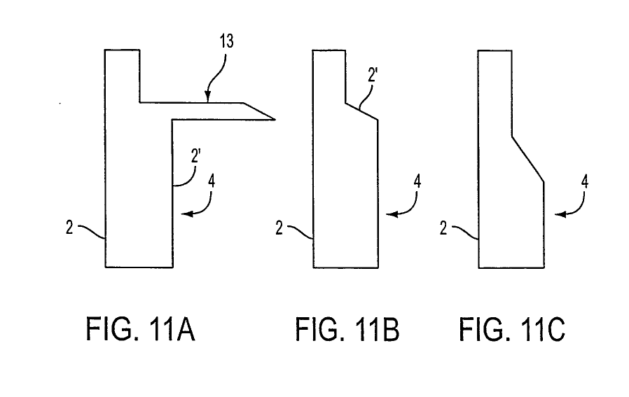

In another embodiment of the invention, corner protectors are implemented to reduce the wafer area required for the design of angled walls. The silicon under the angled walls of the masking layer, like the corners, will be attacked by the etchant, despite being covered by the masking layer and will be etched away at some well defined speed. Mask compensation techniques must be used so that the final structure has the intended angled wall in the correct position. FIGS. 11a-11c depict another embodiment of the invention, using a masking and etching design for an angled wall on a silicon wafer 1 that does not require as much space on the wafer 1 to position the angled wall in the correct location.

As depicted in FIG. 11a, by putting a step 2′ in the wall 2, and protecting it by a stub-type corner protector 13, the silicon under the angled wall masking layer will not propagate as far during the etching process. Instead, the silicon under the stub-type corner protector 13 and step 2′ will be consumed while the unprotected silicon 4 of the wafer 1 is being etched during the etching process. The angle of this wall is not controllable—it will end up being the fastest etch plane for a given etchant. For silicon etched 25% w/w TMAH at 95 degrees Centigrade, this is found to be a shallow angle of roughly 70 degrees, which is very suitable for many purposes. For example, if a taper is desired on a plug, this structure could be used.

In yet another embodiment of the invention, small springs are formed on the surface of the wafer to provide compliance, instead of the long silicon cantilever currently used in known millimeter wave packaging and assembly systems to press the conductive surfaces together. In each of these embodiments, the purpose of the compliant structure is to provide mechanical force for electrical contact or mechanical locking in a micromachined plug and socket system. The following non-limiting embodiments of the resilient, compliant structures provide different amounts of force and different amounts of vertical movement.

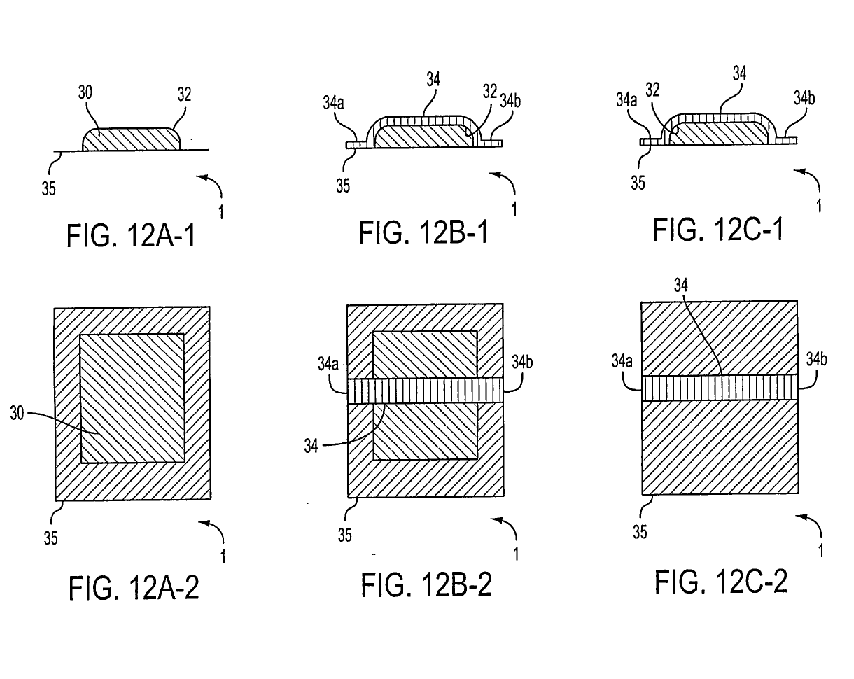

FIGS. 12a-12c depict an embodiment of a conducting structure with compliance that can be used in a micromachined plug and socket system. This compliance ensures good DC contact between the plug side and socket side metal of the opposing structures, while still allowing for manufacturing variations. The structure 34 is a loop formed from a conductive material, such as metal, that extends above the surface of the wafer, as shown in FIG. 12c1. The structure 34 is attached to the wafer at ends 34a and 34b. The metal structure 34 of the loop is electroplated nickel. More preferably, the metal structure 34 of the loop may be plated with gold. In addition, other resilient conductive materials can be used.

FIGS. 12a-12c depict a method for manufacturing an embodiment of a conducting structure with compliance that can be used in a micromachined plug and socket system. In this method, a patterned sacrificial layer 30, for example photoresist, is patterned on a wafer 1 over a metallized area 35, to form a bump, as depicted in FIGS. 12a1 and 12a2. A thin “seed layer” 32 of metal, or another conducting material, may be deposited over this sacrificial layer 30, if subsequent deposition steps require it. Next, a stripe is patterned over this sacrificial layer 30 using standard photolithographic techniques. Then, metal is deposited in the stripe pattern to form the structure 34, as depicted in FIGS. 12b1 and 12b2. One possible method is to use electroplated or electrolessly plated nickel, but other metals and techniques are possible. Next, the “seed layer” 32, if deposited, is removed. Then, the sacrificial layer 30 is removed by a chemical or plasma process, leaving a suspended structure 34 that can bend in the middle, as depicted in FIGS. 12c1 and 12c2. The suspended structure 34 is attached to the wafer 1 at both ends 34a, 34b. Additionally, the suspended structure 34 can then be plated with gold, if desirable.

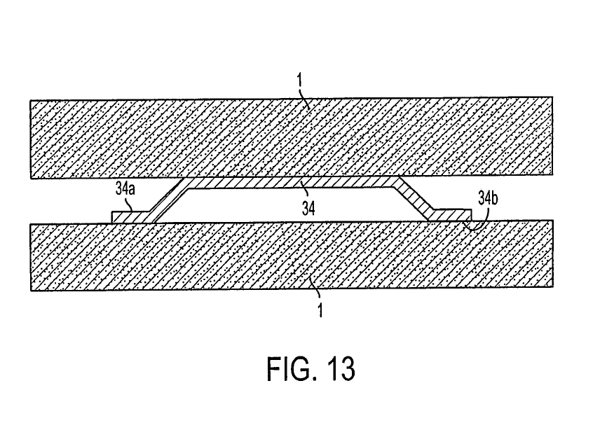

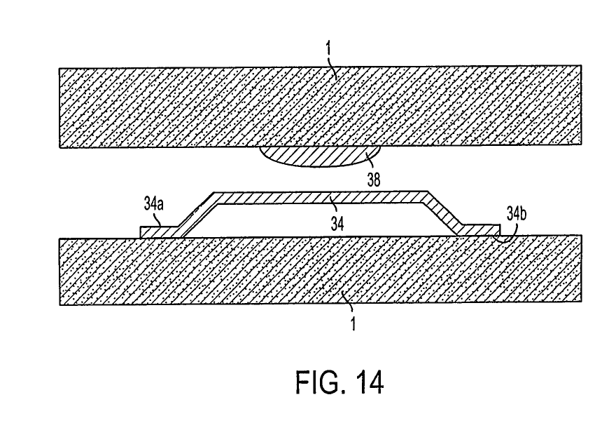

The suspended structure 34 can be formed on the wafer surface and used only for compliance or, the ends 34a, 34b can be formed on a conductor 35, and used as a conductive and compliant structure. In addition, an opposing structure can mate with the suspended structure 34, as shown in FIG. 13. One of the mating structures on the opposing structure might be a simple bump 38 of metal, as shown in FIG. 14, or another compliant structure.

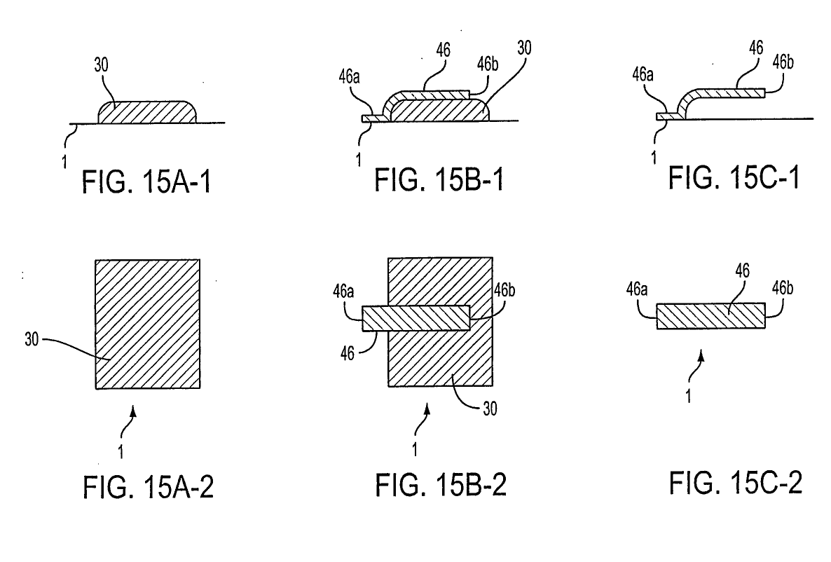

Another embodiment of a compliant structure that is depicted in FIGS. 15a-15c. In this embodiment, one end 46a of the suspended structure 46 is attached to the wafer surface 1, while the other end 46b of the suspended structure 46 is suspended above the wafer surface 1. The structure 46 in the embodiment of FIG. 9 will bend more easily than the embodiment with both ends 34a, 34b of the suspended structure 34 attached to the surface of the wafer 1 depicted in FIG. 12c.

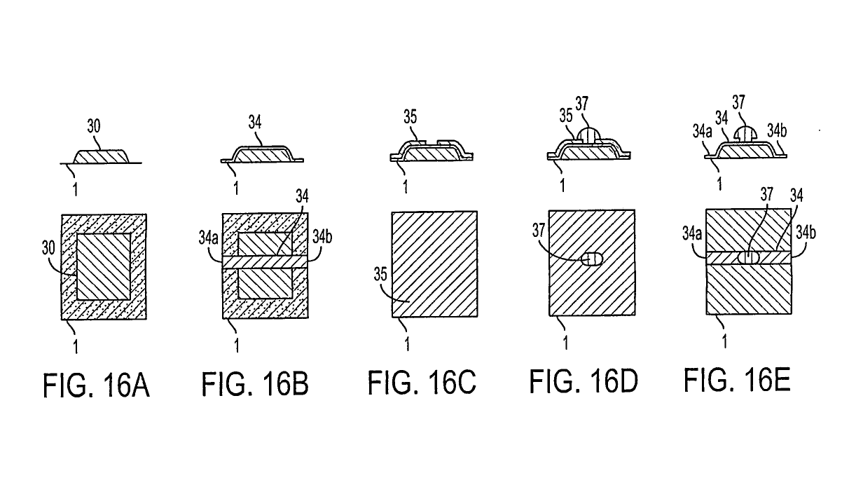

In yet another embodiment of the reduced area compliant structure, a “Button” of metal or other material, as depicted in FIGS. 16a-16e, can be deposited on top of the compliant structure, using photolithography and plating.

As shown in FIGS. 16a-16e, a resist 35 is patterned over the compliant structure 34 before the sacrificial layer 30 is removed or the silicon wafer 1 from underneath the metal structure 34 is etched. Next, a bump 37, or button, of metal or other material, preferably nickel, is plated on top of the structure 34. The addition of this bump 37, or button, gives the structure 34 increased height, so that the structure 34 can span a larger gap between two opposing members of an interconnect device to make contact with an opposing structure, such as another compliant structure, bump, or the like. This additional bump 37 can be provided on any of the embodiments described herein.

As shown in FIG. 16d, the bump 37, if plated, can be plated above the thickness of the photoresist pattern 35. This will give it a rounded edge and a “mushroom” shape. This rounded shape would be useful if two bumps were making contact by sliding horizontally together.

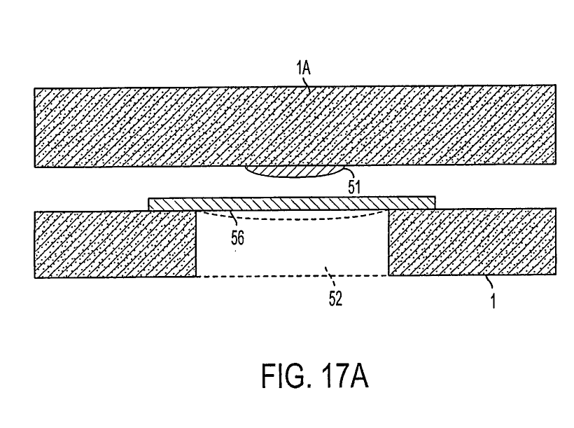

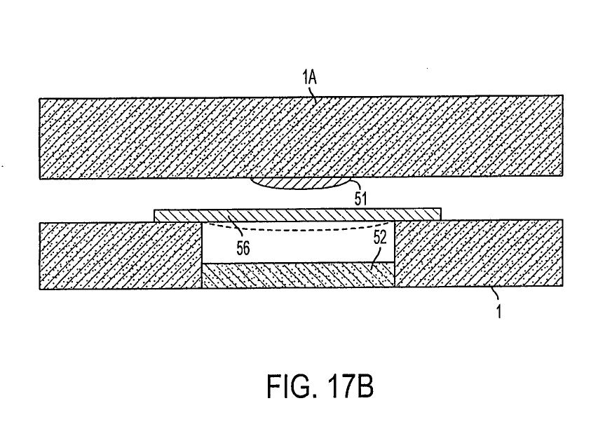

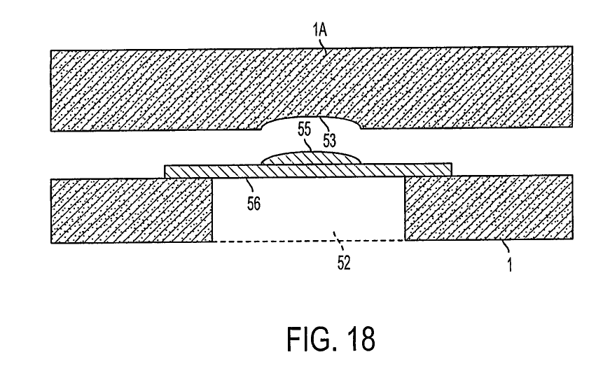

FIG. 17a depicts yet another embodiment of a compliant structure that reduces the wafer area per device. In this embodiment, the compliant structure is a metal structure 56 which is formed on the surface of the wafer 1. A portion 52 of the silicon wafer underneath the metal structure 56 has been etched away to create a void under the metal structure 56. The size of the portion 52 that is etched away can be any size or depth, provided at least one end of the metal structure 56 is supported by the wafer 1 and the metal structure has enough clearance between the wafer 1 and the metal structure 56 to flex, as shown in FIG. 17b. In other embodiments, the structure 56 can be formed from other materials, other than metal, suitable for this purpose, although metal is the preferred material. More preferably, the structure 56 is formed from nickel. In addition, metal structure 56 can mate with an opposing structure 1A. The opposing structure 1A can also have a bump 51, as shown in FIGS. 17a and 17b, or another compliant structure. In another embodiment, the compliant structure 56 can be formed with a bump 55 for engaging the opposing structure 1A and/or with a notch in the opposing structure 1A, as shown in FIG. 18.

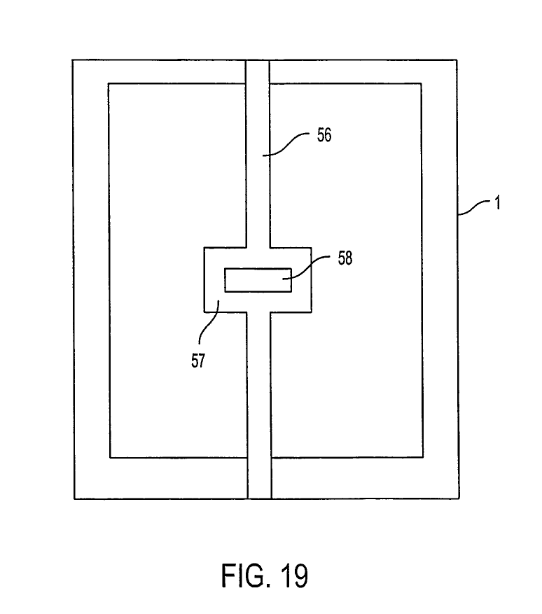

In another embodiment, a metal structure 56 can be formed on a wafer 1 with a rectangular section 57 at a point along its length, as shown in FIG. 19. Other shapes may also be formed on the metal structure 56. Further, a hole 58 may be formed in the rectangular section 57. The hole 58 serves to allow the silicon portion 52 under the metal structure 56 to be completely undercut by the anisotropic etch. The hole 58 further serves to allow elastic, flexural, and torsional compliance to be utilized in the structure, making it a versatile compliant structure. Various shapes and sizes for the hole 58 may be used. The metal structure 56 of this embodiment can mate with a simple metal bump, or the like, on an opposing surface, as well as another compliant structure. One way of obtaining compliance is to twist the metal structure 56.

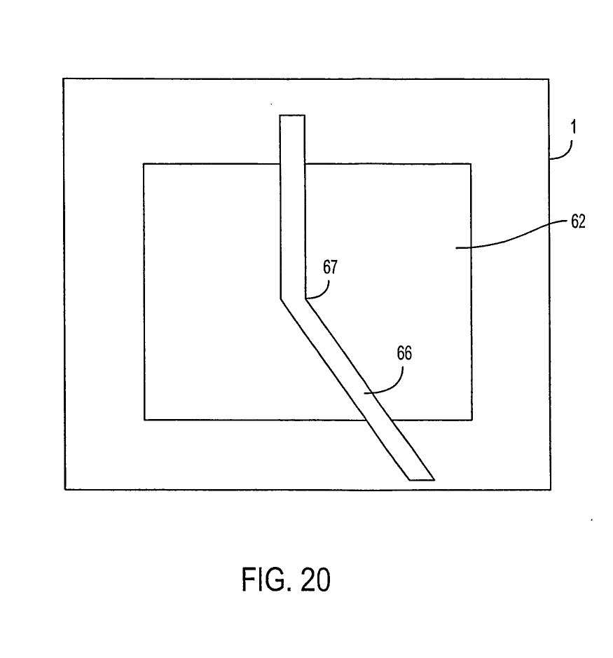

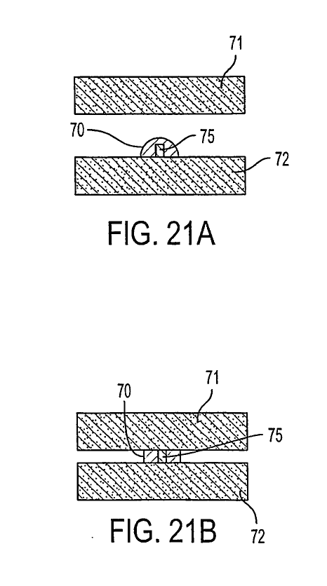

Another embodiment of a reduced area compliant structure is depicted in FIG. 20. In this embodiment, the compliant structure is a metal structure 66 formed on the wafer 1. The metal structure 66 is formed with a bend 67 along its length.

The bend 67 in the metal structure 66 provides a means of flexing the metal structure 66 and ensures that the anisotropic etch will fully undercut the portion of the silicon wafer 62 from underneath the structure 66.

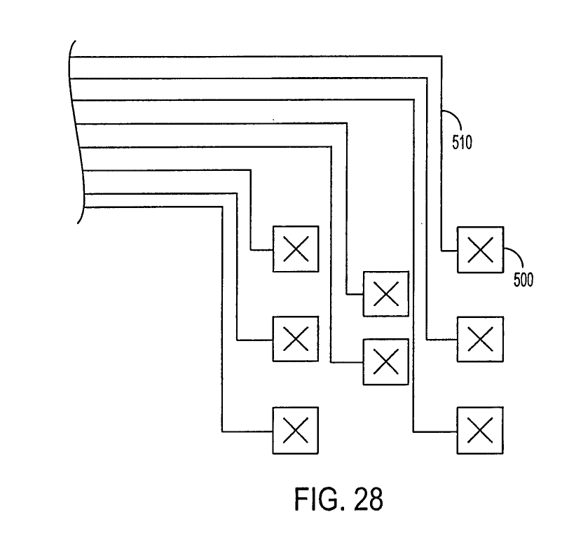

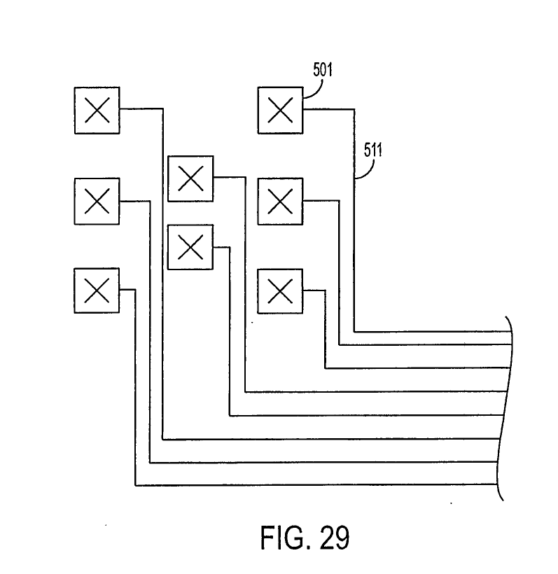

In another embodiment, an array (square, hexagonal close-packed, or another type) of any embodiment of the compliant structures may be used to transfer multiple signal lines (i.e., 10-15 or more) from a socket to a plug-type transition using minimal space. For example, as shown in FIG. 28, a geometrical array of the individual compliant structures 500, or mixtures of the different compliant structure types, can be formed to enable high density signal line packing for reduced wafer area occupation. Multiple signal lines 510 are brought into an area on the package and distributed out to a geometrical array of compliant structures on the plug input. The geometrical array could be square, rectangular, circular, hexagonal close-packed, or a wide variety of other dense packing geometries. Using a minimum of wafer real estate, multiple signal lines can be transferred from socket to plug simultaneously and with constant electrical contact. A second compliant structure 501 array exists on the socket output, as shown in FIG. 29, to receive the array of signal lines 510 from the plug. The image of the array could be similar or dissimilar to the array itself. The signal lines 510, 511 are designed to not overlap each other when plugged together so that no lines are short circuited together. This embodiment occupies significantly less wafer area than arranging the signal lines 510, 511 in a line, either vertically or horizontally. One process for making such a reduced area compliant structure, as shown in FIGS. 19 and 20, is to deposit a thick metal structure, for example, plated nickel, on top of a masking layer. Silicon dioxide might be used as a masking layer. Next, the metal can be shaped by first applying photoresist, patterning the photoresist to form the desired shape, then plating the metal through the photoresist mask. Finally, the masking layer can be patterned and the entire structure is etched in an anisotropic silicon etchant until the substrate under the metal structure is etched away.

A way to solve the problems with surface mounting packages and solder bonding wafers is to provide the package with a set of standoffs 75 or “stilts” between the bottom side 72, and the top side 71, as depicted in FIGS. 21a-21b. These standoffs 75 will keep the lower surface 72 of the package from contacting the circuit board 71, thus maintaining it at a uniform height above the board 72. Not only should this eliminate shorting of adjacent contacts by the spreading of the solder, but it also should result in a more repeatable RF connection to the board. The standoffs 75 can be micromachined or integrally formed on the surface of the silicon wafer, for example, by etching the silicon wafer away and forming little silicon posts, by forming bumps on the silicon wafer using deposited material, such as electroplated metal, or by using other suitable means to form the standoffs.

In another embodiment, the standoffs 75 can be positioned outside of the metal or solder pad, such as around the edge of the micromachined package or within non-electrical areas of the micromachined package. These standoffs can be micromachined or integrally formed on the surface of the wafer or formed by electroplating. The standoffs can be either metal or a dielectric material if they do not need to conduct current.

In yet another embodiment of the invention, standoffs are used for controlling the spread of solder or other bonding material when two wafers are bonded together to form the micromachined plug and socket system. Instead of patterning a large bond area with uninterrupted bonding material, which can flow outside of its original area when the wafers are heated and pressed together, the bonding material is applied in only a portion of the bond area, with spacers or standoffs used to control the final height of the material. For example, a pattern of stripes of nickel can be patterned in the bond area, with solder on top. During the reflow process the solder can flow in the spaces between the stripes, and will not be forced out into unwanted areas. Other patterns for the standoffs can also be used, for example posts or squares of nickel. Other standoff materials can also be used. Standoffs could also be formed by etching the substrate itself with a protective mask on top to form bumps or stripes. The standoffs and solder can be put on either of the opposing surfaces of the two wafer.

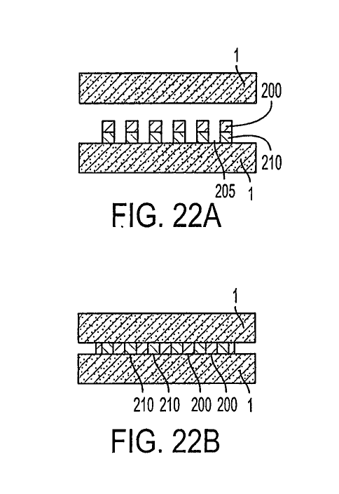

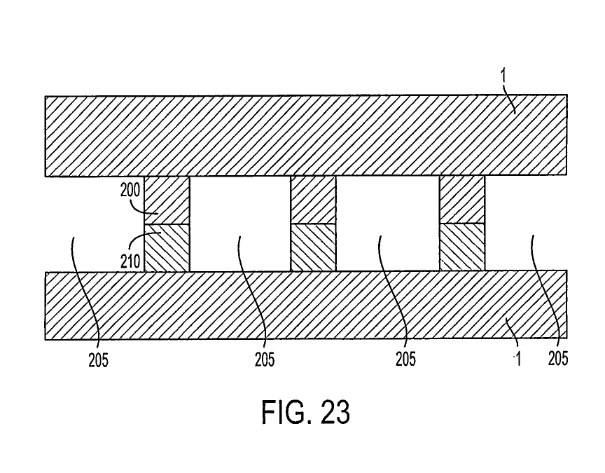

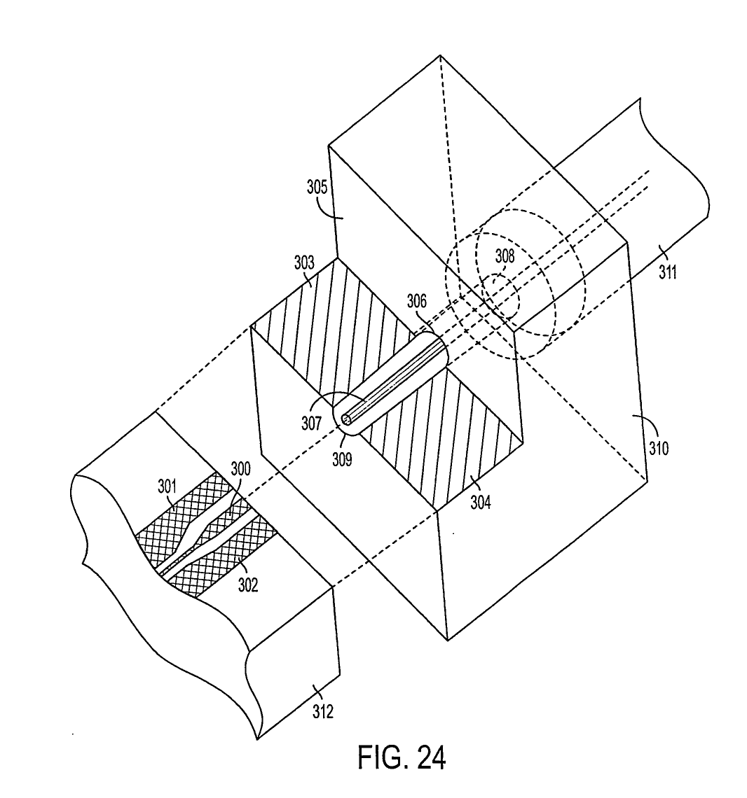

A non-limiting embodiment of a striped standoff is depicted in FIGS. 22A and 22B. When the wafers 1 are brought together and heated, the solder 210 flows into the spaces 205 between the nickel stripes 210, and does not move out laterally into unwanted areas. In the preferred embodiment depicted in FIG. 23, nickel stripes 210 are used in addition to the solder stripes 200. First, nickel is plated through a striped mask pattern, as shown in FIG. 23. Second, solder 200 is plated through the striped mask pattern on top of the nickel stripes 210. As the wafers 1 and 1′ are pressed together and heated, the solder stripes 200 melt and flow into the spaces 205. However, the added height of the nickel stripes 210 results in less lateral outflow, or spreading, of the solder 200. The mask pattern stripe width, distance between stripes, and the thickness of the nickel stripes determine the amount of volume to capture the reflowed bonding material. The same geometry determines the volume of the bonding material which will reflow. Therefore, by adjusting the thicknesses of the nickel and bonding material layers, it can be assured that there will be enough space for the bonding material to flow into.” The nickel stripes 210 and solder stripes 200 can be positioned so that the width of the spaces 205 is large enough to contain all of the lateral outflow of solder 200. In addition, the height of the nickel stripes 210 will determine the spacing between the upper and lower wafers 1 and 1′ of the package. Thus, when the wafers 1 and 1′ are pressed together, the nickel should make contact with the opposing wafer surface, facilitating a well controlled height. Furthermore, the nickel stripes 210 serve as barriers to prevent the solder 200 from flowing into unwanted areas of the package.

The process of applying the solder comprises applying a photomask. Next, nickel is electroplated through the mask. Then, without removing the mask, solder is plated on top of the electroplated nickel. Next, the photomask is removed. Then, the two wafers are pressed together and heated up. The solder sticks to the nickel stripes and any extra solder flows into the spaces 205 between the nickel stripes.

In one non-limiting embodiment, both surfaces have standoffs and bonding material. In yet another non-limiting embodiment, the standoffs are on one surface and the bonding material is on the other surface. In yet another non-limiting embodiment, the nickel structures 210 are posts instead of stripes.

In yet another embodiment of the present invention, gold pads are formed on the bottom of a micromachined package. RF lines are run through the wafer, using via holes, to connect the circuit inside of the package to the pads on the outside of the package. Solder and bumps are then formed on the pads. Then, the whole assembly is mounted down to a conventional circuit board. In this way, RF (or even DC) signals can be connected from the inside of the package down to a standard printed circuit board. The purpose of the bumps is twofold—to keep the solder from squeezing out and shorting adjacent pads. The other purpose is that at high enough frequencies, the variation in the thickness and width of the solder that has squeezed out can alter the capacitance and other transmission line properties of the interconnect, degrading the system performance. The bumps can be formed by depositing material (such as electroplated metal) or by etching the silicon wafer away and forming little silicon posts.

Another embodiment of the present invention omits the use of solder as the attachment mechanism. Instead the metal or otherwise micromachined standoffs are used as mechanical supports and spacers for a conductive liquid material placed directly onto the circuit board, such as conductive epoxy, to mount the components. The standoffs serve the same purpose as before, to limit the vertical excursion of the package relative to the circuit board to control both the height and shape of the adhesive material.

An interconnected assembly of micromachined electronics packages will form a complete RF circuit. It may be desirable, under some circumstances, to mount this assembly in a conventional metal housing to provide protection from the environment and also to provide an interface to standard connector types. It is also desirable to improve RF performance and reduce the final product size.

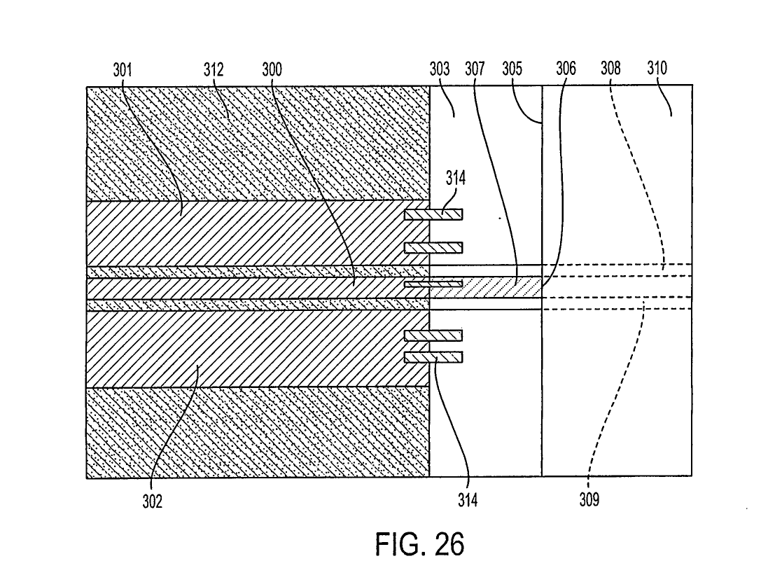

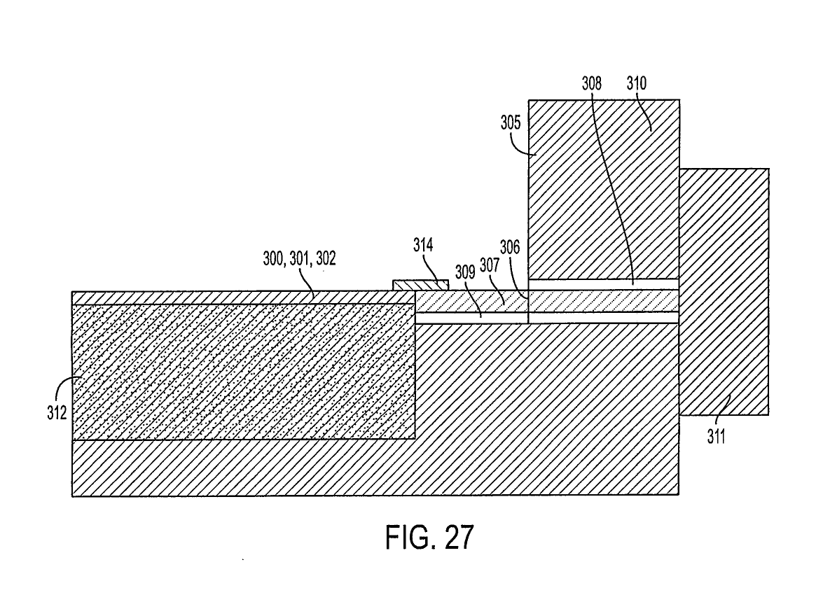

FIGS. 24-27 depict a non-limiting embodiment of an interconnection scheme for interfacing industry standard RF and optoelectronic connectors (for example SMA, 2.9 mm, 2.4 mm, 1.85 mm, 1.0 mm) with circuit boards or packaging technologies in hermetic and non-hermetic applications. In FIGS. 24-27, the problems of the prior art are overcome by providing a Glass bead to Open Coax Shelf (or CPW shelf) and an Open Coax Shelf (or CPW shelf) to a CPW or a microstrip circuit. These are broadband, high frequency connector to circuit board transitions. The non-limiting embodiment in FIGS. 24-27 is a cascade of two transitions which increase the flexibility of package and circuit board transitions to industry standard RF connectors. The glass bead pin coax structure makes a coax to coax transition from the 50 ohm glass bead 311 soldered into the housing wall 310 to a short 50 ohm air dielectric coax 308 using the glass bead center pin 307. From this air dielectric coax 308, the pin 307 exits the housing wall 310 at location 306 and enters the inside of the housing cavity where the circuit board 312 is mounted. However, instead of entering the housing interior without any surrounding metal (i.e. a very high impedance transmission line), the housing wall 310 transitions to a shelf structure 303, 304 whose height off the housing floor is the same as the top of the glass bead pin 307. A semi-circular cross-section of a cylinder is milled out along the direction of the glass bead pin 307 (before the bead is installed). This forms a semi-circular air dielectric 309 around the glass bead pin 307 whose radius is carefully designed to form a 50 ohm open-top coax line with the glass bead pin 307. This structure is inherently very low loss due to air dielectric and also exhibits minimal dispersion over frequency. The open coax shelf (or CPW shelf) maintains 50 ohm impedance from DC to over 40 GHz and additionally can be scaled by using a different radius glass bead pin diameter and CPW shelf air dielectric diameter to be 50 ohm single-moded well beyond 100 GHz. This shelf transition is similar to a coax line that has been sliced longitudinally down a point at the top of the glass bead pin. It naturally presents a center conductor (pin 307) and two ground planes (shelves 303, 304) in a co-planar arrangement. Therefore, it is the ideal transition from the glass bead pin 307 to a CPW circuit board 312 while still maintaining full compatibility with a microstrip transition directly to the CPW shelf structure by only connecting the microstrip center conductor 300 to the glass bead center pin 307.

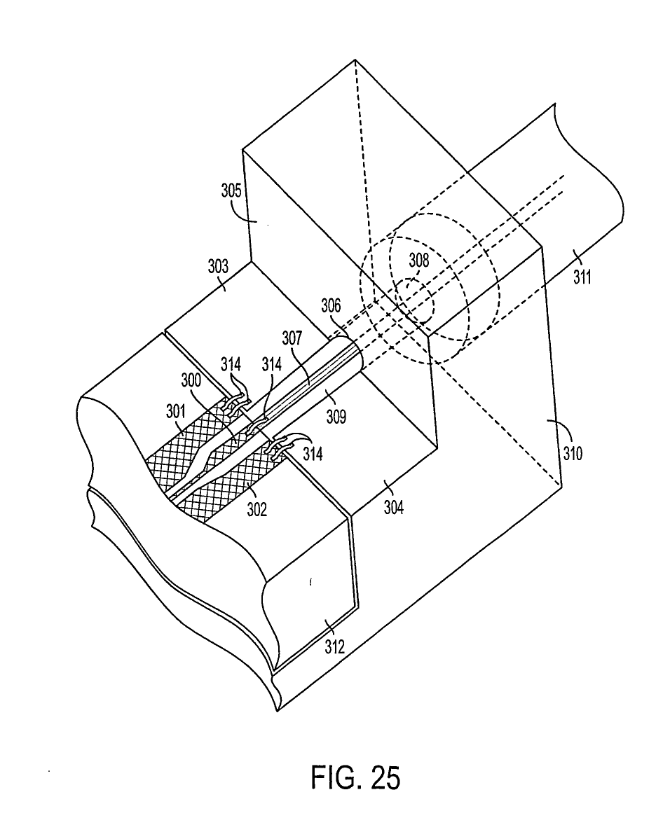

The circuit board 312 is mounted up against the shelf structure 303, 304. The pin 307 is aligned with the center pin 300 and the shelves 303, 304 are aligned with the ground planes 301, 302, as shown in FIG. 25. In one embodiment, ribbon or wire bonds 314 are used to connect CPW center conductor 300 to the glass bead pin 307. The ground planes 301, 302 are connected directly to the conductive metal shelves 303, 304 on either side of the pin 307 using wire or ribbon bonds 314. In another embodiment, the pin 307 and shelves 303, 304 are connected to the CPW lines 300, 301, 302 using a flip-chip mounted thin or thick film circuit with matching metallization using an electrically conductive adhesive or solder. In another embodiment, a microstrip circuit board is mounted up against the shelf and a ribbon bond or wire bond is used to connect the microstrip center conductor 300 to the glass bead pin 307. In another embodiment, the microstrip center conductor 300 and glass bead pin 307 are connected using a flip chip mounted thin or thick film circuit with matching metallization. In a related embodiment, the end of the CPW center conductor 300 or microstrip center conductor is flared out wider at the circuit edge to tune out any ribbon bond 314 mismatches at the interface.

The advantages of this invention are the direct CPW transition it naturally forms. By not converting to microstrip first on the circuit board, significant reductions are realized in wafer die area and circuit board area, circuit losses, and system complexity. Since CPW is naturally a wideband, non-dispersive medium, the transition from CPW to coax is inherently wideband with constant impedance and effective dielectric constant versus frequency. This allows the use of thicker and higher dielectric constant circuit board materials (normally very dispersive in microstrip) without frequency variations.

Since the open coax shelf extends and maintains a 50 ohm impedance riding along with the glass pin as it enters the housing, this shelf structure and pin extension 303, 304, 307 can be made an arbitrarily long length without suffering any impedance mismatch or inductive mis-tuning. This allows the full use of automated assembly equipment such as pick and place and wire/ribbon bonding since the circuit directly attaches to the housing floor without needing to slip underneath the glass bead pin. The interface from circuit to pin can be pulled away from the tall housing wall 310 so the automated tools have enough distance to reach into the housing. The glass bead pin can be installed before or after circuit attachment to the housing since it does not intrude into the circuit mounting area at all. This is a high volume manufacturing approach to forming circuit to connector transitions.

Mechanical compliance is also achieved by using a ribbon or wire bond attachment 314 from the center conductor 300 and ground planes 301, 302 to the glass bead pin 307 and shelves 303, 304. Since the connection is flexible rather than hard soldered or epoxied, any thermal mismatches between circuit 312 and housing 310 will be absorbed by the flexible connection 314 between the center pin 307 and housing shelves 303, 304 with the CPW conductors 300, 301, 302 on the circuit board 312.

A circuit board 312 depicted in the preferred embodiment is a silicon wafer, however, the wafer could be any dielectric substrate used for RF work, such as Duroid, Rogers 3003 or 4003, alumina, etc. Preferably, the three CPW conductor lines 300, 301, 302 are formed from gold.

The process of manufacturing a non-limiting embodiment of the CPW to coax shelf transition of the present invention begins with a block. The block can be made of metal or any other conductive material. On the edge, a series of three concentric bores of different depths are performed. The first bore forms the cylindrical cavity that the bead will sit in. The second bore forms a small shelf that the bead sits up against when inserted. The third bore forms the cylindrical cavity to a depth into the housing sidewall equal to the total bead pin length. A horizontal milling step from the top of the metal block then cuts across the cylindrical cavity to form shelves whose height is set to be co-incident with the top of the glass bead pin when its inserted into the first side bore. The edges of the shelves closest to the pin are circular and a set distance from the pin to be a 50 ohm open coaxial line. The glass bead is soldered in to the first bore which sets its depth into the side of the housing when it hits the second circular bore. The pin length is chosen so that when seated properly, the pin extends down the center of the third bore until it comes to the end of the shelf from the horizontal milling step. A second horizontal milling step sets the height of the housing floor so that a circuit board attached to the floor will have its top CPW conductors coincident with the two ground shelves and top of the center glass bead pin. The circuit is surface mounted into the housing. The CPW lines are then connected to the shelf, center pin, and shelf, respectively, using ribbon bonds, wire bonds, or flip chip circuits as discussed above.

An improvement in RF performance and reduction in the final product size can be done using an embodiment of the transition described above. For example, a micromachined package can be fabricated with a standard plug or socket on one part of the package, and a shelf with a coplanar waveguide coming off another part of the package. In this way, a transition from the micromachined package to a conventional connector can be made using minimal space by not having to convert from CPW to microstrip before interfacing with the housing wall.

What is claimed is:

1. A mask layout for a device to be etched in a crystalline wafer, said mask layout comprising:
a crystalline wafer with a masking layer; and
a corner protector having a stub;
wherein said stub has a plurality of bends.

2. The mask layout according to claim 1, wherein said stub has a corner formed only at an end of said stub.

3. The mask layout according to claim 1, wherein said stub makes bends at T-like structures having a first end and a second end.

4. The mask layout according to claim 2, wherein said first end of said stub is connected to a nearest wall of said mask layout.

5. The mask layout according to claim 1, wherein said bends in said stub are positioned so that an end of said stub after said bend is short enough to etch away entirely.

6. The mask layout according to claim 1, wherein said corner protector is folded at least one time, thereby permitting the maskset to fit into tightly configured geometries.

7. The mask layout according to claim 1, comprising a means for changing the relative angle between said bend and a final stub connecting said corner, so that the final etched corner is sharper.

8. The mask layout according to claim 1, wherein said device is a micromachined package including a plug with at least two corners to be protected.

9. The mask layout for a micromachined packaging and assembly system according to claim 1, wherein said device is a micromachined package including a socket with at least two corners to be protected.

10. A mask layout for a micromachined package to be etched in a crystalline wafer, said mask layout comprising:
a crystalline wafer with a masking layer; and
a first corner protector; and
a second corner protector;
wherein said first corner protector and said second corner protector are joined together to achieve a fold.

11. A mask layout for a micromachined package to be etched in a wafer, said mask layout comprising:
a wafer having a frontside and a backside;
a first mask layer applied to said front side of said wafer;
a corner protector having a stub; and
a second masking layer applied to said backside of said wafer;
wherein said first masking layer and said second mask layer are aligned.

12. The mask layout for a micromachined packaging and assembly system according to claim 11, wherein said second masking layer is applied to said backside of said wafer and aligned with said frontside masking layer only at a final portion of said stub where said stub terminates into said corner.

13. In a method for making a micromachined package using a mask layout, said micromachined package formed in a crystalline wafer, and having an angled wall, wherein said angled wall is formed by:
putting a step in a wall of said mask layout on a crystalline wafer;
protecting said step by a corner protector;
consuming said corner protector while said crystalline wafer is etching through; and
consuming said step in said wall, thereby forming an angled wall feature in said device while minimizing the necessary space required on the crystalline wafer.

14. An angled wall propagation structure for a micromachined package, said angled wall propagation structure comprising:
an angled wall;
a step positioned on said angled wall; and
a corner protector extending from the corner of said step, wherein said corner protector has a plurality of bends.

15. The angled wall propagation structure for a micromachined package according to claim 14, wherein said corner protector includes a tapered end, thereby providing more repeatable etching characteristics.

16. The angled wall propagation structure for a micromachined package according to claim 15, wherein said corner protector is tapered in a same direction as said angled wall, thereby providing more repeatable etching characteristics.

17. A method of forming a compliant structure for a micromachined package comprising:
patterning a sacrificial layer on a crystalline wafer over a metallized area to form a bump;
patterning a stripe over said bump using photolithographic techniques;
depositing a material in said stripe; and
removing said sacrificial layer, thereby forming a resilient suspended structure of said material.

18. The method of claim 17, comprising the additional step of forming a button on top of said compliant structure.

19. The method of claim 17, comprising the additional steps of:
patterning a resist over said compliant structure prior to removing said sacrificial layer; and
plating a bump on top of said structure, thereby giving said structure more height so that said structure can span a larger gap to make contact with an opposing structure.

20. The method of claim 19, wherein said button is made of metal.

21. The method of claim 19, wherein said button is formed using photolithography and plating.

22. The method of claim 17, wherein said sacrificial layer is a photoresist.

23. The method of claim 19, wherein a thin seed layer of metal is deposited over said bump.

24. The method of claim 17, wherein said deposited material is metal.

25. The method of claim 17, wherein said deposited material is electroplated nickel.

26. The method of claim 17, wherein said deposited material is electrolessly plated nickel.

27. The method of claim 17, wherein said deposited material is evaporated material.

28. The method of claim 17, wherein said deposited material is sputtered material.

29. The method of claim 23, wherein said seed layer is removed after the metal is deposited in said stripe.

30. The method of claim 17, wherein the sacrificial layer is removed by a chemical process.

31. The method of claim 17, wherein the sacrificial layer is removed by a plasma process.

32. The method of claim 17, wherein at least one of a first side and a second side of the resilient suspended structure mates with an opposing structure.

33. The method of claim 17, further comprising the step of forming the compliant structure with a suspended end, thereby permitting the compliant structure to bend more easily.

34. A compliant structure for a micromachined package, said compliant structure comprising:
a packaging device of a crystalline material; and
a resilient suspended structure having a first end and a second end;
wherein said suspended structure is attached to said packaging device at at least a first end.

35. A compliant structure for a micromachined package according to claim 34, wherein said resilient suspended structure is attached to said crystalline material at said first end and said second end of said resilient suspended structure.

36. A compliant structure for a micromachined package system according to claim 34, wherein said resilient suspended structure further includes a button annexed to said resilient suspended structure.

37. A method of forming a micromachined package with a compliant structure, the method comprising:
forming a resilient structure on a surface of a crystalline wafer; and
etching the wafer from underneath said resilient structure.

38. The method according to claim 37, wherein said resilient structure is metal.

39. The method according to claim 37, wherein said resilient structure is deposited on a masking layer.

40. The method according to claim 39, wherein said resilient structure is formed from plated nickel.

41. The method according to claim 37, comprising the additional steps of:
patterning a resist over said resilient structure prior to etching said wafer from underneath said resilient structure;
plating a bump on said resilient structure, thereby giving said resilient structure more height so that said resilient structure can span a larger gap to make contact with an opposing structure.

42. The method according to claim 37, wherein said resilient structure is shaped by:
applying a photoresist masking layer;
patterning said photoresist masking layer;
plating said resilient structure through said photoresist masking layer;
patterning said photoresist masking layer; and
etching said resilient structure and said wafer using an anisotropic or isotropic etchant.

43. The method according to claim 42, wherein said resilient structure is twisted.

44. The method according to claim 37, wherein said resilient structure has a rectangular shape formed at substantially a midpoint of said structure.

45. The method according to claim 44, wherein said rectangular shape includes a hole therein, thereby allowing the wafer to be completely undercut by an anisotropic etch.

46. The method according to claim 37, wherein said resilient structure mates with a metal bump on an opposing structure.

47. A compliant structure for a micromachined package, said compliant structure comprising:
a wafer including a recess formed therein; and
a resilient structure suspended over said recess.

48. A compliant structure for a micromachined package according to claim 47, wherein said resilient structure includes a bulge formed substantially at the midpoint of the resilient structure.

49. A compliant structure for a micromachined package according to claim 47, wherein said bulge is a rectangular shape having a hole therein.

50. A compliant structure for a micromachined package according to claim 47, wherein said resilient structure comprises at least one bend formed in said resilient structure.

51. A micromachined package comprising:
a first substrate and a second substrate;
a plurality of standoffs disposed between said first substrate and said second substrate, whereby said standoffs maintain a predetermined separation between said first substrate and said second substrate; and
a solder material disposed between said first substrate and said second substrate and surrounding said plurality of standoffs.

52. The micromachined package of claim 51, wherein said standoffs are integral with said first substrate.

53. The micromachined package of claim 51, wherein said standoffs are deposited on a surface of said first substrate.

54. The micromachined package of claim 51, wherein said standoffs are electroplated metal.

55. A micromachined wafer bonding system comprising:
a first wafer;
a second wafer;
a plurality of metal stripes formed in a cross-hatched pattern between and in contact with said first wafer and said second wafer;
a solder material disposed between said stripes and between said first wafer and said second wafer, whereby said solder material bonds said first wafer and said second wafer together.

56. The micromachined wafer bonding system of claim 55, wherein said stripes are made of nickel.

57. The micromachined wafer bonding system of claim 55, wherein a thickness of said stripes is greater than a thickness of said solder.

58. A micromachined wafer bonding process comprising the steps of:
patterning a first wafer with a striped mask pattern, whereby said striped mask pattern forms a cross-hatched pattern;
plating said striped mask pattern with a metal to form a pattern of metal stripes;
plating said striped mask pattern with a solder to form a pattern of a solder on said metal stripes;
reflowing said solder, whereby said solder flows into spaces between said metal stripes; and
pressing a second wafer on said first wafer;
wherein said metal stripes contact said second wafer.

59. A micromachined packaging system comprising:
a first substrate having a plurality of via holes therein, said substrate having a first side and a second side;
a second substrate to be attached to said first side of said first substrate;
a circuit positioned on said second side of said substrate;
a plurality of metal pads formed on said first side of said first substrate, wherein said metal pads have a plurality of standoffs integrally formed on said metal pads and disposed between said metal pads and said second substrate;
a plurality of conducting lines disposed in said via holes and electrically connecting said circuit to said metal pads; and
a solder material disposed between said metal pads and said second substrate and surrounding said standoffs.

60. A micromachined packaging and assembly system according to claim 59, wherein said metal pads are made of gold.

61. A coplanar waveguide to coax shelf transition device comprising:
a substrate having a center conductor surrounded by a first ground plane and a second ground plane;
a housing having a housing wall, a first shelf, and a second shelf,
wherein said first shelf is separated from said second shelf by a cylindrical depression;
a center pin having a circular cross section,
wherein said circular pin extends through said housing wall and is disposed in said cylindrical depression;
wherein said central conductor is in electrical contact with said central pin, said first ground plane is in electrical contact with said first shelf, and said second ground plane in electrical contact with said second shelf.

62. The coplanar waveguide to coax shelf transition device according to claim 61, wherein said substrate is a dielectric substrate.

63. The coplanar waveguide to coax shelf transition device according to claim 61, wherein said wafer is made of Duroid, Rogers 3003 or 4003, or alumina.

64. The coplanar waveguide to coax shelf transition device according to claim 61, wherein said center conductor, said first ground plain, and said second ground plain are made of gold.

65. The coplanar waveguide to coax shelf transition device according to claim 61, wherein said cylindrical depression is perpendicular to said housing wall.

66. A compliant structure for a micromachined package comprising a plurality of compliant structures formed in a geometric array.

67. A compliant structure for a micromachined package according to claim 66, wherein said array is a linear, rectangular, square, circular, or hexagonal closed packed array for distributing multiple signal lines from a plug to a socket using a minimal wafer area.

68. A compliant structure for a micromachined package according to claim 66, wherein said package has a plurality of different compliant structures incorporated on said package.

69. The coplanar waveguide to coax shelf transition device according to claim 62,
wherein said substrate is a micromachined circuit from a micromachined plug and socket packaging system.
